(19) United States
(12) Patent Application Publication
(10) Pub. No.: US 2011/0137612 A1
(43) Pub. Date: Jun. 9, 2011

(54) METHODS AND SYSTEMS FOR ESTIMATING LONGITUDINAL RELAXATION TIMES IN MRI

(75) Inventors: Defeng WANG, Hong Kong (CN); Lin SHI, Hong Kong (CN); Pheng Ann HENG, Hong Kong (CN)

(73) Assignee: The Chinese University of Hong Kong, Hong Kong (CN)

(21) Appl. No.: 12/959,267

(22) Filed: Dec. 2, 2010

Related U.S. Application Data
(60) Provisional application No. 61/267,292, filed on Dec. 7, 2009.

(51) Int. Cl. G06F 19/00; G01R 33/44

(52) U.S. Cl. 702/181; 324/309

(57) ABSTRACT

A method and a system for estimating a longitudinal relaxation time in magnetic resonance imaging. The method includes scanning at least one object to form a sequence of data with a plurality of flip angles; regressing linearly the formed sequence of data based on a first signal intensity model associated with the flip angles to obtain an initial estimation for said longitudinal relaxation time; and regressing nonlinearly the formed sequence of data based on a second signal intensity model associated with the flip angles so as to obtain a final estimation for the longitudinal relaxation time, in which the initial estimation is used as an initial guess for the longitudinal relaxation time based on the second signal intensity model.

### CROSS REFERENCE OF RELATED APPLICATIONS

This application claims the benefit of U.S. Provisional Patent Application No. 61/267,292, entitled “METHODS AND SYSTEMS FOR ESTIMATING LONGITUDINAL RELAXATION TIMES IN MRI”, filed on Dec. 7, 2009, the content of which is incorporated by reference herein in its entirety.

### TECHNICAL FIELD

The application relates to methods and systems for estimating longitudinal relaxation times in magnetic resonance imaging (MRI).

### BACKGROUND OF THE INVENTION

A longitudinal relaxation time T₁ is an important intrinsic biophysical property of biological tissues. T₁ is not only useful in tissue characterization for a diagnosis of pathology such as multiple sclerosis (MS), but also in dynamic contrast agent magnetic resonant imaging (MRI) to monitor tumor growth and to assess a treatment therefore.

The original Fast Low Angle Shot (FLASH) sequence was proposed and has now widely been used in a clinical application such as the three-dimensional (3-D) acquisition of the brain at very high spatial resolution, an imaging within a single breath-hold, and dynamic imaging of the beating heart. The signal from a FLASH sequence with a flip angle α follows an Ernst formula which represents the signal intensity as a function of α and other two parameters, namely the proton density M and the longitudinal relaxation time T₁.

Research in the estimation of T₁ map in FLASH is still active. The most popular method for T₁ estimation uses data points from two flip angles for computational efficiency, and researchers are interested in developing even faster T₁ estimation methods. Due to errors in the pulse flip angles, however, the gradient echo sequence is particularly sensitive to systematic errors. Therefore, the T₁ map estimated from multiple flip angles (>2) is essentially more accurate than the two-point estimation as has been proposed by “Tofts P. Quantitative MRI of the Brain, New York: John Wiley & Sons, Inc; 2003. 650p”.

A method for T₁ map estimation using multiple flip angles was first proposed by Fram E K, et. Al, (Fram E K, Herfkens R J, Johnson G A, Glover G H, Karis J P, Shimakawa A, Perkins T G, Pelc N J. Rapid calculation of T1 using variable flip angle gradient refocused imaging, Magn Reson Imaging 1987; 5:3:201-8) and it has been conventionally applied in clinical diagnosis nowadays. In Fram's paper, the Ernst formula was reformulated as a linear regression problem, but the use of linearization alters the essential meaning of the original objective function, which subsequently influences the estimated parameters values.

Jim is commercial software for medical image analysis. The Fitter Tool in Jim v5.0 performs nonlinear least squares regression (fitting) on a series of images that represent different values of a variable. The Fitting Tool can produce the map of T₁ values given the Ernst formula and FLASH images with multiple flip angles as input. However, the Fitter Tool in Jim v5.0 needs a “proper” initial guess for T₁, which is not always easy to acquire and may vary from one dataset to another

### SUMMARY OF THE INVENTION

This disclosure provides a method and a system to estimate parameters of T₁ from a sequence of FLASH MRI scans with multiple (≧2) flip angles.

According to one aspect, there is provided a method for estimating a longitudinal relaxation time in magnetic resonance imaging, comprising:

scanning at least one object to form a sequence of data with a plurality of flip angles;

regressing linearly the formed sequence of data based on a first signal intensity model associated with the flip angles to obtain an initial estimation for said longitudinal relaxation time; and

regressing nonlinearly the formed sequence of data based on a second signal intensity model associated with the flip angles so as to obtain a final estimation for said longitudinal relaxation time, wherein the initial estimation is used as an initial guess for the longitudinal relaxation time based on the second signal intensity model.

According to another aspect, there is provided a system for estimating a longitudinal relaxation time in magnetic resonance imaging, comprising:

a sequence forming unit configured to scan at least one object with a plurality flip angles to form a sequence of data;

a linear regression unit configured to regress linearly the formed sequence of data based on a first signal intensity model associated with the flip angles to obtain an initial estimation for longitudinal relaxation time; and

a nonlinear regression unit configured to regress nonlinearly the formed sequence of data, based on a second signal intensity model associated with the flip angles, so as to obtain a final estimation for the longitudinal relaxation time, wherein the initial estimation is used as an initial guess for the longitudinal relaxation time based on the second signal intensity model.

In this disclosure, the estimation of the parameters is formulated as a constrained nonlinear regression problem, where the constraints guarantee that the solution is reasonable and robust. To ensure the nonlinear optimization problem converge to a good estimation robustly and efficiently, the solution of the linear regression was utilized as the initial estimate of the nonlinear regression.

### BRIEF DESCRIPTION OF THE DRAWINGS

FIG. 1 illustrates a process for estimating a T1 in MRI according to one embodiment of the application.

FIG. 2 illustrates a system for estimating a T1 in MRI according to one embodiment of the application.

FIG. 3 illustrates curve fitting results on a slice of Subject 1 estimated by different methods.

FIG. 4 illustrates an RMSE of the four T1 estimation methods (Fram's method, the Fitter Tool in Jim, COPE and COPE-GPU) on the six subjects as listed in Table 1.

### DETAILED DESCRIPTION OF THE PREFERRED EMBODIMENT

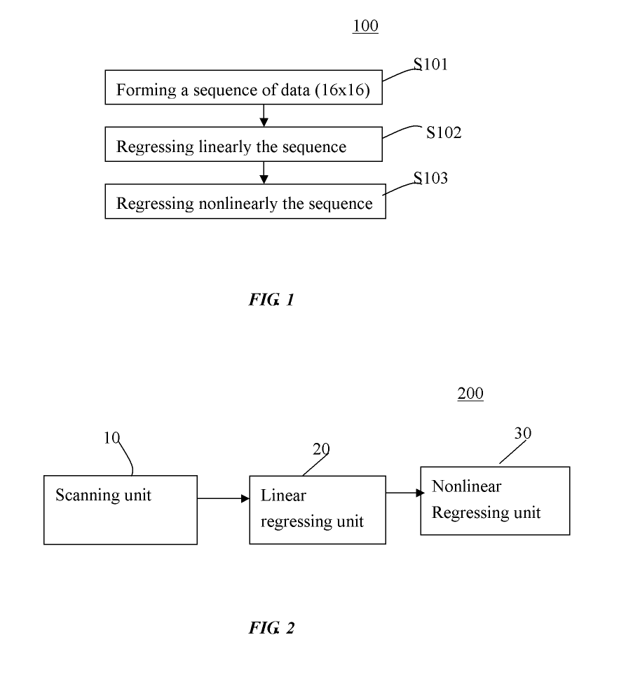

Hereinafter, a process 100 (in the context of the application, it is also referred as “COPE”) for estimating longitudinal relaxation time T1 in MRI according to one embodiment of the present application will be discussed in reference to FIG. 1.

The process 100 begins with step S101, at which at least one object (for example, tissue of six patients) is scanned to form a sequence of data with a plurality flip angles α. The sequence of data may be formed with a conventional MR imaging. For example, the patient undergoes MR imaging by using a head neck coil with a Fast Field Echo (FFE) sequence. The exemplified imaging parameters used in this embodiment to form the sequence of data are listed in Table 1.

TABLE 1

| Subject | |
|---|---|
| ID | Imaging Parameters |
| 1 | 1.5 Tesla; TR = 2.7 ms; TE = 1 ms; Resolution = |
| | 128 × 128 × 25; flip angle = 2°, 10°, 20°, 30° |
| 2 | 1.5 Tesla; TR = 2.7 ms; TE = 1 ms; Resolution = |
| | 128 × 128 × 25; flip angle = 2°, 10°, 20°, 30° |
| 3 | 3.0 Tesla; TR = 4 ms; TE = 1.07 ms; Resolution = |
| | 128 × 128 × 25; flip angles = 2°, 7°, 15° |
| 4 | 3.0 Tesla; TR = 4 ms; TE = 1.67 ms; Resolution = |
| | 240 × 240 × 20; flip angles = 5°, 10°, 15° |
| 5 | 3.0 Tesla; TR = 5.42 ms; TE = 1.65 ms; Resolution = |
| | 240 × 240 × 20; flip angles = 5°, 10°, 15° |
| 6 | 3.0 Tesla; TR = 4 ms; TE = 1 ms; Resolution = |
| | 128 × 128 × 25; flip angles = 2°, 7°, 12°, 15° |

In Table 1, the parameters “1.5 Tesla” and “3.0 Tesla” are the field strength of a MRI scanner. Generally, the larger the field strength is, the better the imaging quality is. “TE” is an Echo Time, which represents the time in milliseconds between an application of 90° pulse in MR imaging and a peak of an echo signal in Spin Echo and Inversion Recovery pulse sequences. “Resolution” in this context is the number of voxels in dataset of the sequence of data, and ‘128×128×25’ represent there are 128, 128, and 25 voxels in the x, y and z directions.

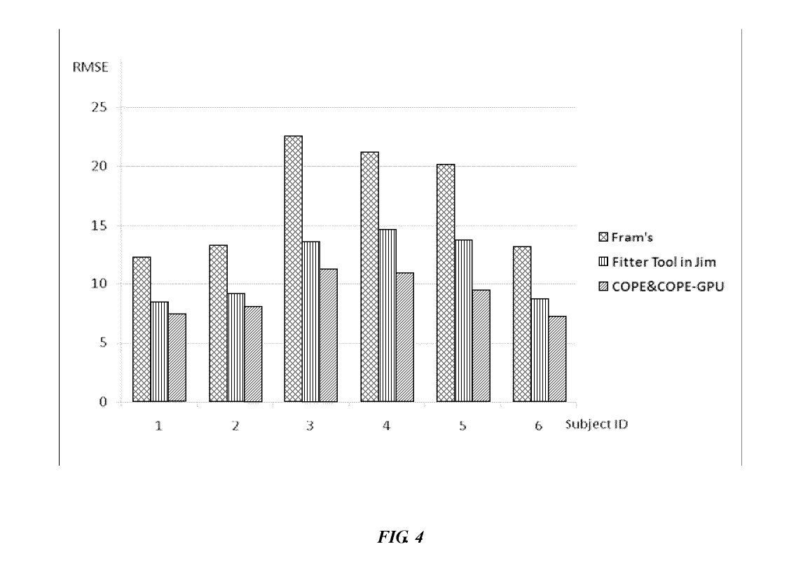

It can be assured theoretically and experimentally that more accurate T₁ can be estimated given more flip angles. As shown in Table 1, Subject 1, 2 and 6 have the data acquired at four flip angles, and the remaining three subjects have been scanned using three flip angles. As one can observe in FIG. 4 as discussed latter, the mean RMSE of all the four methods under testing are significantly smaller in Subjects 1, 2, and 6 than those in Subjects 3, 4, and 5.

Then, at step S102, the formed sequence of data is regressed linearly based on a first signal intensity model to obtain an initial estimation for T1. At step S103, the initial estimation is used as an initial guess to regress nonlinearly the formed sequence of data based on a second signal intensity model, so as to obtain a final estimation for T1, the estimated T1 being utilized for distinguishing different biologic tissues, and monitoring tumor growth and assessing a treatment on the tumor in dynamic contract enhanced MR imaging. The detailed description of step S102 and step S103 are given as below.

### Step S102: Linear Regression

The Ernst formula representing the signal intensity S(α) of the formed sequence of data at a certain flip angle α is formulated as

$$S ( α ) = M \cdot sin ( α ) \cdot \frac{1 - {e}^{( - TR / {T}_{1} )}}{( 1 - cos ( α ) \cdot {e}^{( - TR / {T}_{1} )}} , \qquad 1 )$$

where M denotes a proton density (PD) in respect of the formed sequence of data and T₁ is the longitudinal relaxation time in MRI, assuming TE<<T1.

The Ernst formula is reformulated to obtain a linear model y=ax+b, for example, according to the work “Barbosa S, Blumhardt L D, Roberts N, Lock T, Edwards R H. Magnetic resonance relaxation time mapping in multiple sclerosis: normal appearing white matter and the “invisible” lesion load. Magn Reson Imaging 1994; 12:33-42”. The linear model y=ax+b is presented as below.

$$\frac{S ( α )}{sin ( α )} = E \cdot \frac{S ( α )}{tan ( α )} + M \cdot ( 1 - E ) , \qquad 2 )$$

where

E=e^{(-TR/T}^{₁}⁾. 3)

Compared the linear model as shown in equation 2) with y=ax+b, it is easy to know that:

$$y = \frac{S ( α )}{sin ( α )} , \\ x = \frac{S ( α )}{tan ( α )} ,$$

the slope a=E=e^{(-TR/T}^{₁}⁾ and the intercept b=M·(1−E).

Using a conventional linear regression approach, a and b can be estimated, from which T₁ and M can be further obtained, i.e.,

$${T}_{1} = - \frac{TR}{ln a} , \\ and M = \frac{b}{1 - a} . \qquad 4 )$$

Supposing (αᵢ,S(αᵢ))ᵢ₌₁ⁿ represents n pairs of flip angle αᵢ and the corresponding signal intensity S(αᵢ), and TR represents a Repetition Time. The objective in the linearized formulation is to minimize Σᵢ₌₁ⁿ\hat{d}ᵢ², where the squared error \hat{d}ᵢ² between the estimated value

$$E \cdot \frac{S ( {α}_{i} )}{tan ( {α}_{i} )} + M \cdot ( 1 - E )$$

and the measured value

$$\frac{S ( {α}_{i} )}{sin ( {α}_{i} )}$$

for the i^{th} data point is

$${\hat{d}}_{i}^{2} = {( \frac{S ( {α}_{i} )}{sin ( {α}_{i} )} - E \cdot \frac{S ( {α}_{i} )}{tan ( {α}_{i} )} - M \cdot ( 1 - E ) )}^{2} . \qquad 5 )$$

In this linearization, it is easy and fast to calculate T₁, but the accuracy is reduced as the essential meaning of the original objective function, i.e., Eqn. 5) is altered, which subsequently influences the estimated parameters values. In addition, the values of T₁ and M may be negative because there is no any constraint for the linear regression. The estimated values from this linearized regression, whereas, can be used as good initial guesses for the subsequent nonlinear regression. In one embodiment, this step S102 may be carried out in a processor in a computer or a GPU.

### Step S103: Nonlinear Regression

The step S103 is to resolve the original nonlinear regression formulated in Eqn. 1). The squared error dᵢ² between the estimated value and the measured value for the i^{th} data point is

$${d}_{i}^{2} = {( S ( {α}_{i} ) - \frac{M \cdot sin ( {α}_{i} ) \cdot ( 1 - E )}{1 - cos ( {α}_{i} ) \cdot E} )}^{2} . \qquad 6 )$$

The optimal estimates of M and E can be obtained by solving a constrained nonlinear least squares problem as follows,

$${min}_{M , E} {\sum }_{i = 1}^{n} {d}_{i}^{2} \\ s . t . 0 < E < 1 \\ 0 < M < ∞ . \qquad 7 )$$

The Levenberg-Marquardt (LM) method in the prior art can be used to solve the constrained optimization problem in Eqn. 7) efficiently. The key operation in LM method is the computation of the Jacobian matrix defined by the partial derivatives ∂S(αᵢ)/∂M and ∂S(αᵢ)/∂E, which can be achieved in the following form

$$J = [ \begin{matrix}\frac{sin ( {α}_{1} ) \cdot ( 1 - E )}{1 - cos ( {α}_{1} ) \cdot E} & \frac{M \cdot sin ( {α}_{1} ) \cdot ( cos ( {α}_{1} ) - 1 )}{{( 1 - cos ( {α}_{1} ) \cdot E )}^{2}} \\ \frac{sin ( {α}_{2} ) \cdot ( 1 - E )}{1 - cos ( {α}_{2} ) \cdot E} & \frac{M \cdot sin ( {α}_{2} ) \cdot ( cos ( {α}_{2} ) - 1 )}{{( 1 - cos ( {α}_{2} ) \cdot E )}^{2}} \\ ⋮ & ⋮ \\ \frac{sin ( {α}_{n} ) \cdot ( 1 - E )}{1 - cos ( {α}_{n} ) \cdot E} & \frac{M \cdot sin ( {α}_{n} ) \cdot ( cos ( {α}_{n} ) - 1 )}{{( 1 - cos ( {α}_{n} ) \cdot E )}^{2}}\end{matrix} ] . \qquad 8 )$$

From Eqn. 4), the final estimation of T₁ can be finally obtained based on the optimal estimate of E by

$${T}_{1} = - \frac{TR}{ln ( E )} . \qquad 9 )$$

The parameters estimated from the linear least squares regression served as the initial estimation for the nonlinear regression. Therefore, the linear and nonlinear optimization problems are essentially concatenated.

In addition, the process 100 as discussed in the above may be carried out in a conventional device of CUDA as disclosed in “Lawson C L, Hanson R J. Solving Least Squares Problems. In: Prentice-Hall Series in Automatic Computation. Englewood Cliffs: Prentice-Hall; 1974”. In the case of CUDA (hereinafter “COPE-GPU”), it may take the advantage of the parallel computation power of GPU. Firstly, the code on GPU is invoked and the sequence of data will be transferred between GPU and the host, i.e., CPU, where the data was partitioned into grids. Data sequence stored in each grid was moved to GPU, and then processed on GPU with the proposed concatenated optimization strategy. When GPU finished computing, the results were moved from GPU back to the host memory. The memory allocated on GPU was cleaned up once the whole computation task was completed.

The major contribution of proposing the concatenated optimization strategy for parameter estimation is to illustrate that, for parameter estimation with a nonlinear nature over medical images comprising a certain number of voxels, it is preferred that the acquisition of initial estimates are adaptively and specifically obtained for each individual voxel, instead of setting a fixed initial estimate over the whole image. This initial estimation for the nonlinear optimization as described at step S102 could be acquired using a computationally efficient linear optimization. This heterogeneous initialization strategy could greatly facilitate the search of the global optimum, and thus further improve the fitting accuracy and significantly reduces the computational time. Moreover, with the concatenated optimization strategy, there is no need to set initial estimates in COPE/COPE-GPU, the parameter estimation could be automatically performed, which simplifies its usage by clinicians.

Another key feature contributing to the outperformance of COPE/COPE-GPU lies in that they were naturally formulated as a constrained optimization problem, instead of the conventional unconstrained one. Therefore, unlike the tradition methods, e.g., Fram's method, there is no need in COPE/COPE-GPU to “clap” the estimated values outside the desired range, which could avoid considerable estimation errors. The constrained optimization problem is now solvable using LM algorithm, owing to the recent mathematics advance.

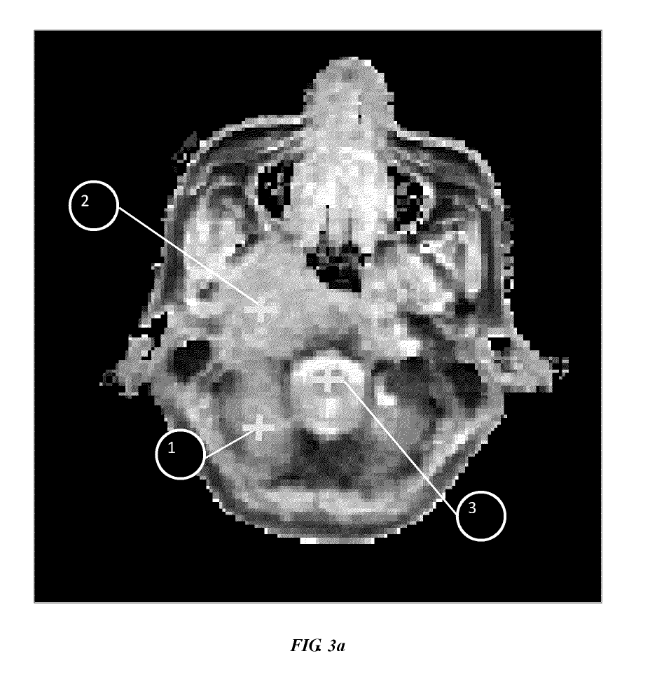

Hereinafter, a system 200 for estimating a T1 in MRI will be discussed in reference to FIG. 2.

As shown in FIG. 2, the system 200 may comprise a sequence forming unit 10, a linear regression unit 20 and a nonlinear regression unit 30.

The sequence forming unit 10 may be configured to scan at least one object with a plurality flip angles α to form a sequence of data. The sequence forming unit 10 may be a 1.5 T Philips Gyroscan ACS-NT clinical whole-body MM system (Philips Medical Systems, best, The Netherlands), or a 3.0 T Philips MRI System (Achieva, X Series, Quasar Dual). The acquisition was not optimized towards one or another fitting algorithm. The unit 10 may acquire from a plurality of patients (for example, six patients) with tumor(s) present in the head and neck. The exemplified imaging parameters used by the unit 10 are listed in Table 1 as stated in the above.

The linear regression unit 20 may be configured to regress linearly the formed sequence of data based on a first signal intensity model to obtain an initial estimation for longitudinal relaxation time T1 and a proton density M, and the nonlinear regression unit 30 is configured to use the initial estimation to regress nonlinearly the formed sequence of data based on a second signal intensity model, so as to obtain a finally estimated longitudinal relaxation time. The detailed processes the units 20 and 30 may be similar to the above steps S201 and S203, and thus the detailed descriptions thereof are omitted herein.

In addition, the system 200 as discussed in the above may be embedded in a conventional device of CUDA, so as to take the advantage of the parallel computation power of GPU.

### Results

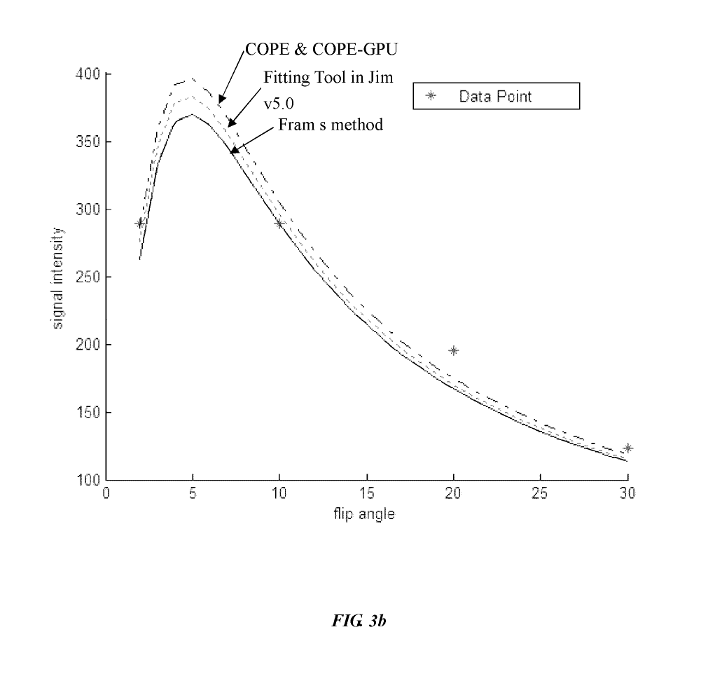

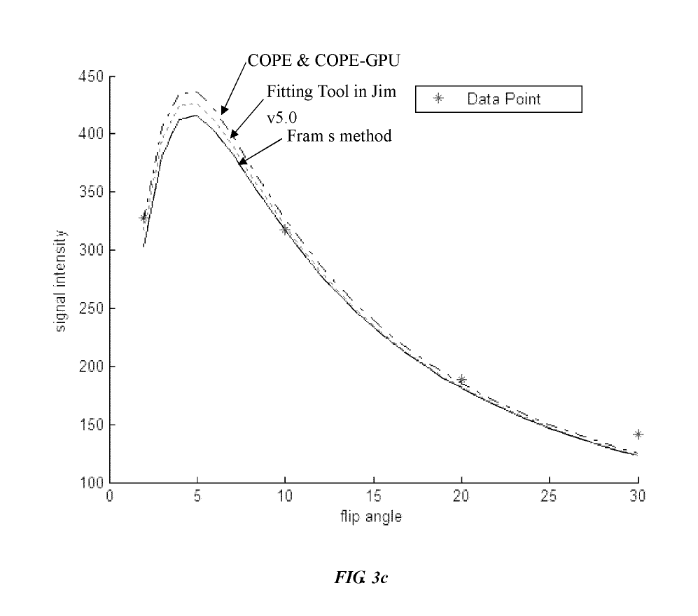

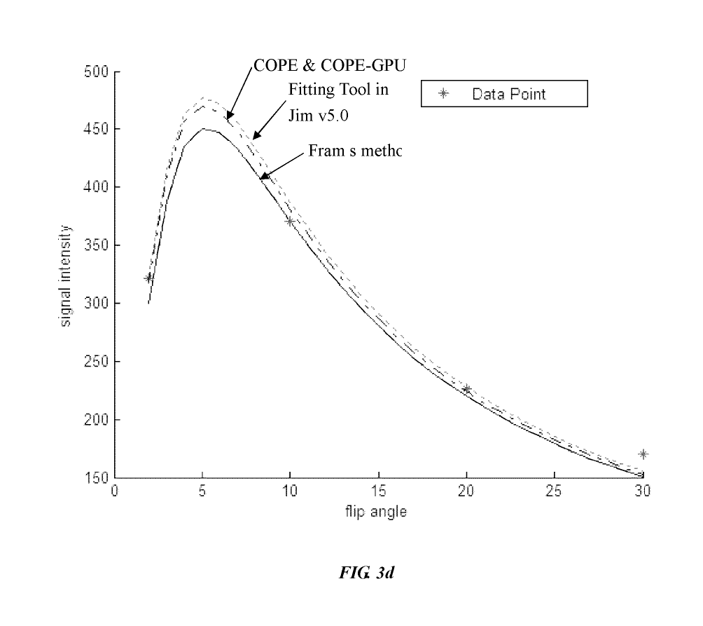

Apart from visually observing the similarity between the fitted curve and measured data points as shown in FIG. 3, the goodness of the fitting result can also be quantified using the Root Mean Squared Error (RMSE), which was defined in our study as follows,

$$RMSE = \frac{1}{n} {\sum }_{i = 1}^{n} {( S ( {α}_{i} ) - M \cdot sin ( {α}_{i} ) \cdot \frac{1 - {e}^{( - TR / T 1 )}}{( 1 - cos ( {α}_{i} ) \cdot {e}^{( - TR / T 1 )}} )}^{2} ,$$

where n represents the number of flip angles in our experiment. The RMSE values for the fitted curves at voxels #1, #2, and #3 in FIG. 3 resulted from the Fram's method, the Fitter Tool in Jim, COPE, and COPE-GPU are given in Table 2.

TABLE 2

| Method | Voxel #1 | Voxel #2 | Voxel #3 |
|---|---|---|---|
| Fram's method | 19.89 | 15.70 | 14.89 |
| Fitter Tool in Jim | 15.08 | 11.10 | 11.06 |
| COPE | 13.03 | 9.43 | 10.14 |
| COPE-GPU | 13.03 | 9.43 | 10.14 |

In Table 2, the RMSE values of the fitted curve are calculated from the Fram's method, the Fitter Tool in Jim, COPE, and COPE-GPU at the voxels “1”, “2”, and “3” in FIG. 3a.

The overall performance comparison among the existing methods, i.e., the Fram's method and the Fitter Tool in Jim, and COPE, and COPE-GPU, in all the six subjects is given in Table 3 in terms of the execution time, and in FIG. 4 as the fitting error. The execution time was recorded based on the corresponding programming language, i.e., Jim in Java, Fram's method and COPE in C++, and COPE-GPU in CUDA. The fitting error over the whole volume data was measured by the mean RMSE, which represents the averaged RMSE of all voxels. Table 3 and FIG. 4 show good accuracy and efficiency achieved by COPE. COPE-GPU inherited the accuracy of COPE but outperformed in its ultra-high speed, which makes it applicable in wide range of clinical uses.

TABLE 3

| Subject | | | | |
|---|---|---|---|---|
| ID | Fram's | Fitter Tool in Jim | COPE | COPE-GPU |
| 1 | 0.14 | 10.65 | 1.08 | 0.02 |
| 2 | 0.16 | 12.15 | 1.14 | 0.02 |
| 3 | 0.12 | 8.82 | 0.93 | 0.02 |
| 4 | 0.21 | 15.78 | 1.61 | 0.03 |
| 5 | 0.20 | 15.53 | 1.56 | 0.03 |
| 6 | 0.15 | 11.23 | 1.14 | 0.02 |

In Table 3, the execution time (min) is listed for the four T1 estimation methods (Fram's method, Fitter Tool in Jim, COPE and COPE-GPU) on the six subjects.

In comparison, the Fitter Tool in Jim requires good initial guess to make the nonlinear fitting approach to the correct result, otherwise the fitting could get stuck in local minimum. For example, using the default setting of initial guess of T₁ and M, i.e., T₁=500 msec, M=500 a.u., on the same set of FLASH MR images (i.e., Subject 1), the averaged RMSE of the Fitter Tool in Jim was 27.86, which was dramatically higher than 8.27 as reported in Table 2, the one acquired with suggested initial guess, i.e., M=10⁴ a.u., T₁=600 msec.

The advantage of the proposed COPE and COPE-GPU over the nonlinear optimization in the Fitter Tool in Jim mainly lies in (1) their automaticity in determining the optimal initial guess for the nonlinear regression, which increased the usability of this method; (2) their high efficiency, which is especially prominent in COPE-GPU.

Due to the wide application of the T₁ relaxation time in studies of contrast agent uptake imaging, perfusion imaging, blood volume estimation, future research efforts can be dedicated to the quantification of T₁ in other types of MRI sequences and the solution of other problems involving parameter estimations. The fitting technique can also be further enhanced by formulating the least squares error optimization as a weighted regression problem by assigning, for example, the signal of smaller flip angle with a larger weight, as FLASH imaging is essentially more reliable in low flip angles. Another possible alternative to improve the fitting accuracy is to reduce the influence of the outlier points, by adopting, e.g., robust regression. Last but not least, as GPU is specifically powerful in the computation tasks that could be decomposed into independent components each having high arithmetic intensity, which is the case in many tasks related to medical image analysis, extensive application of general-purpose GPU on medical image computing deserves further exploration.

Features, integers, characteristics or combinations described in conjunction with a particular aspect, embodiment, implementation or example of this disclosure are to be understood to be applicable to any other aspect, embodiment, implementation or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

What is claimed is:

1. A method for estimating a longitudinal relaxation time in magnetic resonance imaging, comprising:
scanning at least one object to form a sequence of data with a plurality of flip angles;
regressing linearly the formed sequence of data based on a first signal intensity model associated with the flip angles to obtain an initial estimation for said longitudinal relaxation time; and
regressing nonlinearly the formed sequence of data based on a second signal intensity model associated with the flip angles so as to obtain a final estimation for said longitudinal relaxation time, wherein the initial estimation is used as an initial guess for the longitudinal relaxation time based on the second signal intensity model.

2. The method of claim 1, wherein the regressing linearly further comprising:
regressing linearly the formed sequence of data based on the first signal intensity model to obtain an initial estimation for a proton density (PD) in respect of the formed sequence of data, which contributes to determine the initial and final estimations for the longitudinal relaxation time.

3. The method of claim 2, wherein the first signal intensity model is set up by a squared error between estimated values and the measured values for data points in said object.

4. The method of claim 3, wherein said estimated values are represented as
$$E \cdot \frac{S ( {α}_{i} )}{tan ( {α}_{i} )} + M \cdot ( 1 - E ) ,$$
and saw measured values are represented as
$$\frac{S ( {α}_{i} )}{sin ( {α}_{i} )} ,$$
where,
E=e^{(-TR/T}^{₁}⁾, TR representing a known Repetition Time;
αᵢ represents i^{th} flip angle of the plurality flip angles α;
S(αᵢ) represents a signal intensity of the formed sequence of data at a certain flip angle αᵢ;
M represents said proton density (PD); and
T₁ represents the longitudinal relaxation time.

5. The method of claim 2, wherein the first signal intensity model is represented by minimizing (Σᵢ₌₁ⁿ\hat{d}ᵢ²),
where,
$${\hat{d}}_{i}^{2} = {( y - a \cdot x - b )}^{2} , y = \frac{S ( {α}_{i} )}{sin ( {α}_{i} )} , a = E , x = \frac{S ( {α}_{i} )}{tan ( {α}_{i} )} , \\ b = M \cdot ( 1 - E ) ;$$
αᵢ represents i^{th} flip angle of the plurality flip angles α;
S(αᵢ) represents a signal intensity of the formed sequence of data at a certain flip angle αᵢ;
E=e^{(-TR/T}^{₁}⁾, TR representing a known Repetition Time;
M represents the proton density (PD); and
T₁ represents the longitudinal relaxation time.

6. The method of claim 5, wherein the regressing linearly further comprises:
obtaining the initial estimation for T₁ by rule of
$${T}_{1} = - \frac{TR}{ln a} ,$$
and
obtaining the initial estimation for M by rule of
$$M = \frac{b}{1 - a} .$$

7. The method of claim 2, wherein the second signal intensity model is set up by rule of
$${min}_{M , E} {\sum }_{i = 1}^{n} {d}_{i}^{2}$$
$$s . t . 0 < E < 1$$
$$0 < M < ∞$$

8. The method of claim 7, wherein the regressing nonlinearly further comprises:
applying a Levenberg-Marquardt (LM) method to the second signal intensity model such that an optimal estimate for E is determined.

9. The method of claim 8, wherein the regressing nonlinearly further comprises:
determining the final estimation of T₁ based on the determined optimal estimate for E by rule of
$${T}_{1} = - \frac{TR}{ln ( E )} .$$

10. The method of claim 1, wherein the sequence of data comprises a FLASH sequence.

11. The method of claim 1, wherein the object comprises a biological tissue.

12. The method of claim 1, wherein the scanning and regressing linearly and nonlinearly are carried out in a CPU of a computer.

13. The method of claim 1, wherein the scanning and regressing linearly and nonlinearly are carried out in a GPU.

14. A system for estimating a longitudinal relaxation time in magnetic resonance imaging, comprising:
a sequence forming unit configured to scan at least one object with a plurality flip angles to form a sequence of data;
a linear regression unit configured to regress linearly the formed sequence of data based on a first signal intensity model associated with the flip angles to obtain an initial estimation for longitudinal relaxation time; and
a nonlinear regression unit configured to regress nonlinearly the formed sequence of data, based on a second signal intensity model associated with the flip angles, so as to obtain a final estimation for the longitudinal relaxation time, wherein the initial estimation is used as an initial guess for the longitudinal relaxation time based on the second signal intensity model.

15. The system of claim 14, wherein the linear regression unit is further configured to regress linearly the formed sequence of data based on the first signal intensity model to obtain an initial estimation for a proton density (PD) in respect of the formed sequence of data, which contributes to determine the initial and final estimations for the longitudinal relaxation time.

16. The system of claim 15, wherein the first signal intensity model is set up by a squared error between estimated values and the measured values for data points in said object.

17. The system of claim 16, wherein said estimated values are represented as
$$E \cdot \frac{S ( {α}_{i} )}{tan ( {α}_{i} )} + M \cdot ( 1 - E ) ,$$
and said measured values are represented as
$$\frac{S ( {α}_{i} )}{sin ( {α}_{i} )} ,$$
where,
E=e^{(-TR/T}^{₁}⁾, TR representing a known Repetition Time;
αᵢ represents i^{th} flip angle of the plurality flip angles α;
S(αᵢ) represents a signal intensity of the formed sequence of data at a certain flip angle αᵢ;
M represents said proton density (PD); and
T₁ represents the longitudinal relaxation time.

18. The system of claim 15, wherein the first signal intensity model is represented by minimizing (Σᵢ₌₁ⁿ\hat{d}ᵢ²),
where,
$${\hat{d}}_{i}^{2} = {( y - a \cdot x - b )}^{2} , y = \frac{S ( {α}_{i} )}{sin ( {α}_{i} )} , a = E , x = \frac{S ( {α}_{i} )}{tan ( {α}_{i} )} , \\ b = M \cdot ( 1 - E )$$
αᵢ represents i^{th} flip angle of the plurality flip angles α;
S(αᵢ) represents a signal intensity of the formed sequence of data at a certain flip angle αᵢ,
E=e^{(-TR/T}^{₁}⁾, TR representing a known Repetition Time,
M represents the proton density (PD), and
T₁ represents the longitudinal relaxation time.

19. The system of claim 18, wherein the linear regression unit is further configured to obtain the initial estimation for T₁ by rule of
$${T}_{1} = - \frac{TR}{ln a} ,$$
and obtain the initial estimation for M by rule of
$$M = \frac{b}{1 - a} .$$

20. The system of claim 15 wherein the second signal intensity model is set up by rule of
$${min}_{M , E} {\sum }_{i = 1}^{n} {d}_{i}^{2}$$
$$s . t . 0 < E < 1$$
$$0 < M < ∞ .$$

21. The system of claim 20, wherein the nonlinear regression unit is configured to apply a Levenberg-Marquardt (LM) method to the second signal intensity model such that an optimal estimate of E is determined.

22. The system of claim 21, wherein the nonlinear regression unit is configured to determine the final estimation of T₁ based on the determined optimal estimate of E by rule of
$${T}_{1} = - \frac{TR}{ln ( E )} .$$

22. The system of claim 14, wherein the sequence of data comprises a FLASH sequence.

23. The system of claim 14, wherein the object comprises a biological tissue.

24. A GPU comprising the system of claim 14.

25. A method for estimating a longitudinal relaxation time in a device comprising a sequence forming unit, a linear regression unit and a nonlinear regression unit, comprising:
scanning, with the sequence forming unit, at least one object to form a sequence of data with a plurality of flip angles;
regressing linearly, with the linear regression unit, the formed sequence of data based on a first signal intensity model associated with the flip angles to obtain an initial estimation for said longitudinal relaxation time; and
regressing nonlinearly, with the nonlinear regression unit, the formed sequence of data based on a second signal intensity model associated with the flip angles so as to obtain a final estimation for said longitudinal relaxation time, wherein the initial estimation is used as an initial guess for the longitudinal relaxation time based on the second signal intensity model.

26. A method for estimating a longitudinal relaxation time in magnetic resonance imaging, comprising:
scanning, in an MR imaging, at least one object to form a sequence of data with a plurality of flip angles;
regressing linearly, with a processor, the formed sequence of data based on a first signal intensity model associated with the flip angles to obtain an initial estimation for said longitudinal relaxation time; and
regressing nonlinearly, with the processor, the formed sequence of data based on a second signal intensity model associated with the flip angles so as to obtain a final estimation for said longitudinal relaxation time, wherein the initial estimation is used as an initial guess for the longitudinal relaxation time based on the second signal intensity model.

27. The method of claim 26, wherein the professor comprises a GPU.
